(19) United States
(12) Patent Application Publication
(10) Pub. No.: US 2024/0222418 A1
(43) Pub. Date: Jul. 4, 2024

(54) VERTICALLY STACKED ELECTRONIC DEVICE AND METHOD FOR MANUFACTURING SAME

(71) Applicant: POINT ENGINEERING CO., LTD., Chungcheongnam-do (KR)

(72) Inventors: Bum Mo AHN, Gyeonggi-do (KR); Seung Ho PARK, Gyeonggi-do (KR); Tae Hwan SONG, Gyeonggi-do (KR)

(73) Assignee: POINT ENGINEERING CO., LTD., Chungcheongnam-do (KR)

(21) Appl. No.: 18/537,830

(22) Filed: Dec. 13, 2023

(30) Foreign Application Priority Data
Dec. 29, 2022 (KR) 10-2022-0189454

(51) Int. Cl. H01L 27/15; H01L 33/44; H01L 33/62

(52) U.S. Cl. CPC H01L 27/15; H01L 33/44; H01L 33/62; H01L 2933/0025; H01L 2933/0066

(57) ABSTRACT

Proposed is a vertically stacked electronic device that enables the implementation of high-resolution displays by stacking individual LEDs vertically, and a method for manufacturing the vertically stacked electronic device.

### CROSS REFERENCE TO RELATED APPLICATION

The present application claims priority to Korean Patent Application No. 10-2022-0189454, filed Dec. 29, 2022, the entire contents of which is incorporated herein for all purposes by this reference.

### BACKGROUND OF THE INVENTION

### Field of the Invention

The present disclosure relates to a vertically stacked electronic device and a method for manufacturing the same and, more particularly, to a vertically stacked electronic device in which multiple micro LEDs are stacked vertically to form a single pixel and a method for manufacturing the vertically stacked electronic device.

### Description of the Related Art

A liquid-crystal display (LCD) is the most widely used display at present. However, LCD-based displays require a backlight (LED, CCFL), leading to problems such as greater thickness, lower power efficiency, and narrower viewing angles. In the case of an organic light-emitting diode (OLED) display, which has emerged as an alternative, power efficiency is improved compared to LCDs, but there are problems such as low durability and burn-in (deterioration) due to the use of organic materials.

An inorganic micro light-emitting diode (micro-LED) display, which has recently attracted attention, is an inorganic material-based device that has largely resolved the durability issue mentioned above. Moreover, micro-LEDs have better brightness than existing OLEDs, and like OLEDs, unused devices may be turned off, making it possible to express perfect black. That is, micro-LED displays can be a technology that complements the shortcoming of OLEDs while maintaining advantages of the OLEDs.

Typically, for a micro-LED display, each pixel contains a configuration of red, green, and blue micro-LED subpixels.

In this regard, Korean Patent Application Publication No. 10-2022-0133387 discloses “MICRO LED DISPLAY” in which a pixel is implemented by arranging red, green, and blue micro-LEDs horizontally.

However, when individual LEDs are arranged horizontally, a large horizontal space is utilized, which poses clear limitations in manufacturing high-resolution displays.

### DOCUMENTS OF RELATED ART

### Patent Documents

(Patent Document 0001) Korean Patent Application Publication No. 10-2022-0133387

### SUMMARY OF THE INVENTION

Accordingly, the present disclosure has been made keeping in mind the above problems occurring in the related art, and the present disclosure is intended to provide a vertically stacked electronic device capable of implementing a high-resolution display by stacking individual LEDs vertically and a method for manufacturing the vertically stacked electronic device.

In order to achieve the above objective, according to an embodiment of the present disclosure, there is provided a vertically stacked electronic device formed by stacking a plurality of micro-LEDs in a vertical direction. The electronic device may include: a substrate; a first micro-LED located on the substrate; a second micro-LED located on the first micro-LED; a third micro-LED located on the second micro-LED; a common electrode provided through the third micro-LED, the second micro-LED, and the first micro-LED; a first electrode that penetrates the electronic device and is electrically connected to the first micro-LED; a second electrode that penetrates the electronic device and is electrically connected to the second micro-LED; and a third electrode that penetrates the electronic device and is electrically connected to the third micro-LED.

Meanwhile, in order to achieve the above objective, according to an embodiment of the present disclosure, there is provided a method for manufacturing a vertically stacked electronic device including a plurality of micro-LEDs. The method may include: providing an LED stack including the plurality of micro-LEDs; providing a pad electrode in a penetration region formed by etching the LED stack; providing a protective film on surfaces of the LED stack and the pad electrode; selectively removing the protective film provided on the surface of the pad electrode; and providing a bonding electrode in the penetration region.

In addition, in the selectively removing the protective film, the protective film, where the pad electrode is located, may be selectively irradiated with a laser.

A vertically stacked electronic device according to an embodiment of the present disclosure can provide the effect of implementing high-density pixels by stacking individual LEDs in a vertical direction.

Furthermore, a vertically stacked electronic device according to an embodiment of the present disclosure can provide the effect of selectively irradiating and etching a protective film using a laser.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a view showing a vertically stacked electronic device according to an embodiment of the present disclosure;

FIG. 2 is a view showing an LED stack including one micro-LED;

FIG. 3 is a view showing an LED stack including two micro-LEDs;

FIG. 4 is a view showing an LED stack including three micro-LEDs;

FIG. 5 is a view showing a state in which a pad electrode is provided in a penetration region formed by etching a part of an LED stack;

FIG. 6 is a view showing a state in which a protective film is provided on the surfaces of an LED stack and a pad electrode;

FIG. 7 is a view showing a state in which the protective film provided on the surface of the pad electrode is selectively removed;

FIG. 8A is a view showing a state in which the protective film on the part other than the surface of the pad electrode is etched;

FIG. 8B is a view showing a state in which the protective film on the part other than the surface of the pad electrode is etched; and

FIG. 8C is a view showing a state in which the protective film on the surface of the pad electrode is selectively etched according to an embodiment of the present disclosure.

### DETAILED DESCRIPTION OF THE INVENTION

Those skilled in the art will be able to devise various devices which, although not explicitly described or shown herein, embody the principles of the disclosure and are included within the spirit and scope of the disclosure. In addition, it should be understood that all conditional terms and examples listed herein are, in principle, expressly intended only for the purpose of understanding the inventive concept and are not limited to the specifically enumerated embodiments and states as such.

The above objects, features and advantages will become more apparent through the following detailed description in conjunction with the accompanying drawings, and accordingly, those skilled in the art to which the disclosure pertains will be able to easily practice the technical idea of the disclosure.

Embodiments described herein will be described with reference to idealized drawings of the present disclosure. Accordingly, embodiments of the present disclosure are not limited to the specific form shown, but also include changes in the form generated according to the manufacturing process.

In describing various embodiments, components that perform the same function will be given the same names and the same reference numbers for convenience even if the embodiments are different. In addition, the expression “on” does not only mean direct contact, but also includes cases where other layers are involved. In addition, the expression “penetrating A” does not only mean penetrating the entirety of A, but also includes penetrating a partial layer of A. In addition, the expression “electrical connection” between two components does not only mean direct contact, but also includes indirect connection with a conductive material in between. Furthermore, description of the configuration and operation already described in other embodiments will be omitted for convenience.

Hereinafter, a vertically stacked electronic device 1 according to an embodiment of the present disclosure will be described.

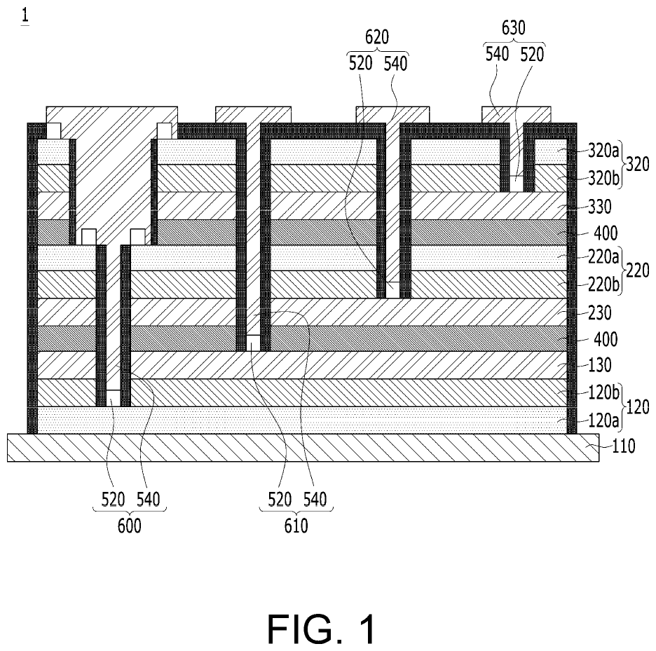

FIG. 1 is a view showing the vertically stacked electronic device 1 according to an embodiment of the present disclosure.

Referring to FIG. 1, the vertically stacked electronic device 1 according to the embodiment of the present disclosure may be formed by stacking a plurality of micro-LEDs 12 in a vertical direction. The vertically stacked electronic device 1 may include: a substrate 11 or 110; a first micro-LED 120 located on the substrate 11 or 110; a second micro-LED 220 located on the first micro-LED 120; a third micro-LED 320 located on the second micro-LED 220; a common electrode 600 provided through the third micro-LED 320, the second micro-LED 220, and the first micro-LED 120; a first electrode 610 penetrating the electronic device and electrically connected to the first micro-LED 120; a second electrode 620 penetrating the electronic device and electrically connected to the second micro-LED 220; and a third electrode 630 penetrating the electronic device and electrically connected to the third micro-LED 320.

An individual LED stack may include: the substrate 11; a micro-LED 12 positioned on the substrate 11; and a transparent electrode 13 positioned on the micro-LED 12.

The substrate 11 may support the components of the individual LED stack 10. In addition, the substrate 11 or 110 may support the components of the vertically stacked electronic device 1. The substrate 11 may support the micro-LED 12 by contacting the micro-LED 12, and may be separated from the micro-LED 12 during the manufacturing stage.

The micro-LED 12 may include an n-type semiconductor 12a and a p-type semiconductor 12b, and may further include an active layer (not shown) between the n-type semiconductor 12a and the p-type semiconductor 12b.

The color of light emitted by the micro-LED 12 may be determined depending on the materials of the n-type semiconductor 12a and the p-type semiconductor 12b. That is, the micro-LED 12 may emit light at a wavelength corresponding to the energy band gap in a p-n junction region.

The active layer may be injected with electrons and holes combining with each other to emit light, and may be composed of a single quantum well (SQW) or multiple quantum well (SQW) structure. However, the active layer is not limited thereto.

The transparent electrode 13 may be made of indium tin oxide (ITO), but is not limited thereto. The transparent electrode 13 may pass light generated from the micro-LED 12 and may electrically connect the micro-LED 12 and a power source.

The vertically stacked electronic device 1 may include the substrate 11 or 110, the first micro-LED 120, the second micro-LED 220, the third micro-LED 320, the common electrode 600, the first electrode 610, the second electrode 620, and the third electrode 630.

The first micro-LED 120 may be made of a red LED, a green LED, or a blue LED. The second micro-LED 220 may be made of a red LED, a green LED, or a blue LED. The third micro-LED 320 may be made of a red LED, a green LED, or a blue LED.

In this case, the first micro-LED 120 to the third micro-LED 320 may each be composed of LEDs that emit different colors. The first micro-LED 120, the second micro-LED 220, and the third micro-LED 320 may each be made of one or two of GaAs, GaP, GaAsP, and GaN. However, the materials of the first micro-LED 120 to the third micro-LED 320 are not limited thereto.

The common electrode 600 may be electrically connected to the first micro-LED 120, the second micro-LED 220, and the third micro-LED 320. That is, the common electrode 600 may receive a negative voltage or a positive voltage and transmit the received negative voltage or positive voltage to the plurality of micro-LEDs 12. Since the common electrode 600 needs to be connected to all micro-LEDs 120, 220, and 320, the common electrode 600 may penetrate the third micro-LED 320 and the second micro-LED 220 from the upper surface of the vertically stacked electronic device 1, and extend up to the first micro-LED 120. In addition, the common electrode 600 may be formed through a portion of the first micro-LED 120.

At this time, the common electrode 600 may be directly connected to the plurality of micro-LEDs 12 or indirectly connected to the plurality of micro-LEDs 12 with a conductive material disposed in between.

The common electrode 600 may have a step so as to be connected to all the first micro-LED 120, the second micro-LED 220, and the third micro-LED 320. The common electrode 600 may include: a first region contacting the first micro-LED 120; a second region formed to be narrower than the first region and contacting the second micro-LED 220; and a third region formed to be narrower than the second region and contacting the third micro-LED 320.

The lower surfaces of the first to third regions may respectively contact the upper surfaces of the n-type semiconductors 12a of the first micro-LED 120 to the third micro-LED 320. The common electrode 600 may contact all of the first micro-LED 120 to the third micro-LED 320 by having a step.

The first electrode 610 may be electrically connected to the first micro-LED 120. That is, the first electrode 610 may receive a positive voltage or a negative and transmit the received negative voltage or positive voltage to the first micro-LED 120. Since the first electrode 610 needs to be connected to the first micro-LED 120, the first electrode 610 may penetrate the third micro-LED 320 and the second micro-LED 220 from the upper surface of the vertically stacked electronic device 1, and extend to the first micro-LED 120 or to a first transparent electrode 130.

At this time, the first electrode 610 may be directly connected to the first micro-LED 120 or indirectly connected to the first micro-LED 120 with a conductive material disposed in between.

The second electrode 620 may be electrically connected to the second micro-LED 220. That is, the second electrode 620 may receive a positive voltage or a negative voltage and transmit the received negative voltage or positive voltage to the second micro-LED 220. Since the second electrode 620 needs to be connected to the second micro-LED 220, the first electrode 610 may penetrate the third micro-LED 320 from the upper surface of the vertically stacked electronic device 1, and extend to the second micro-LED 220 or to a second transparent electrode 230.

At this time, the second electrode 620 may be directly connected to the second micro-LED 220 or indirectly connected to the second micro-LED 220 with a conductive material disposed in between.

The third electrode 630 may be electrically connected to the third micro-LED 320. That is, the third electrode 630 may receive a positive voltage or a negative voltage and transmit the received negative voltage or positive voltage to the third micro-LED 320. Since the third electrode 630 needs to be connected to the third micro-LED 320, the third electrode 630 may extend from the upper surface of the vertically stacked electronic device 1 to the third micro-LED 320 or to a third transparent electrode 330.

At this time, the third electrode 630 may be directly connected to the third micro-LED 320 or indirectly connected to the third micro-LED 320 with a conductive material disposed in between.

To be specific, the common electrode 600 may be electrically connected to the n-type semiconductors 12a, 120a, 220a, and 320a of the first micro-LED 120, the second micro-LED 220, and the third micro-LED 320 (n-type). In this case, the first electrode 610, the second electrode 620, and the third electrode 630 may be electrically connected to the p-type semiconductors 12b, 120b, 220b, and 320b (or the transparent electrodes 13, 130, 230, 330) of the first micro-LED 120, the second micro-LED 220, and the third micro-LED 320, respectively (n-type).

On the other hand, the common electrode 600 may be electrically connected to the p-type semiconductors 12b, 120b, 220b, and 320b of the first micro-LED 120, the second micro-LED 220, and the third micro-LED 320. In this case, the first electrode 610, the second electrode 620, and the third electrode 630 may be electrically connected to the n-type semiconductors 12a, 120a, 220a, and 320a (or the transparent electrodes 13, 130, 230, 330) of the first micro-LED 120, the second micro-LED 220, and the third micro-LED 320, respectively (p-type).

As such, in the vertically stacked electronic device 1, when the common electrode 600 is used as a positive electrode, the first electrode 610 to the third electrode 630 may be used as a negative electrode, whereas when the common electrode 600 is used as a negative electrode, the first electrode 610 to the third electrode 630 may be used as a positive electrode.

The first micro-LED 120, the second micro-LED 220, and the third micro-LED 320 may each be driven independently, and through a combination thereof, may emit light of various colors.

Continuing to refer to FIG. 1, the vertically stacked electronic device 1 may include a first stack 100, an inverted second stack 200, and an inverted third stack 300 in that order from the bottom.

The first stack 100 may include the first substrate 110, the first micro-LED 120, the first transparent electrode 130 in that order from the bottom. The second stack 200 may include a second substrate 210, the second micro-LED 220, and the second transparent electrode 230 in that order from the bottom. The third stack 300 may include a third substrate 310, the third micro-LED 320, and the third transparent electrode 330.

The vertically stacked electronic device 1 according to the embodiment of the present disclosure may include the first stack 100, the inverted second stack 200, and the inverted third stack 300. At this time, the second stack 200 and the third stack 300 may be in a state in which the second substrate 210 and the third substrate 310 are removed, respectively.

The first micro-LED 120 may include the first n-type semiconductor 120a and the first p-type semiconductor 120b in that order from the bottom. The second micro-LED 220 may include the second n-type semiconductor 220a and the second p-type semiconductor 220b in that order from the bottom. The third micro-LED 320 may include the third n-type semiconductor 330a and the third p-type semiconductor 320b in that order from the bottom. However, depending on the purpose for which the common electrode 600 is used as a positive electrode or a negative electrode, the positions of the n-type semiconductor 12a and the p-type semiconductor 12b may be changed.

In the following, the second stack 200 and the third stack 300 of the vertically stacked electronic device 1 described with reference to FIG. 1 are obtained by removing the second substrate 210 and the third substrate 310, respectively.

The vertically stacked electronic device 1 according to the embodiment of the present disclosure may include the first stack 100, the inverted second stack 200, the inverted third stack 300, and a bonding layer 400 for bonding the first stack 100 and the inverted second stack 200, and for bonding the inverted second stack 200 and the inverted third stack 300.

The vertically stacked electronic device 1 may include the common electrode 600, the first electrode 610, the second electrode 620, and the third electrode 630, each of which may be formed by penetrating at least a portion of the vertically stacked electronic device 1 vertically.

In addition, the vertically stacked electronic device 1 may be provided with a protective film 530 to electrically insulate the common electrode 600 from the first to third stacks. The protective film 530 may be provided on the side of the vertically stacked electronic device 1. In addition, the protective film 530 may be provided on the upper surface of the vertically stacked electronic device 1 in an area where the common electrode 600, the first electrode 610, the second electrode 620, and the third electrode 630 do not protrude. In addition, the protective film 530 may be provided on the sides of the common electrode 600, the first electrode 610, the second electrode 620, and the third electrode 630 in a penetration region 510, and may be provided between the first stack 100, the inverted second stack 200, the inverted third stack 300 in the penetration region 510.

The vertically stacked electronic device 1 is formed by stacking the first micro-LED 120, the second micro-LED 220, and the third micro-LED 320 in a vertical direction, thereby saving horizontal space. As a result, the vertically stacked electronic device 1 may implement a display with high-density pixels.

Next, a method for manufacturing the vertically stacked electronic device 1 according to an embodiment of the present disclosure will be described.

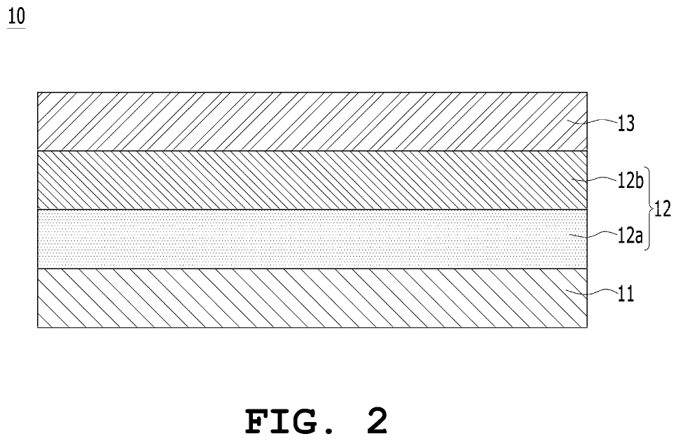

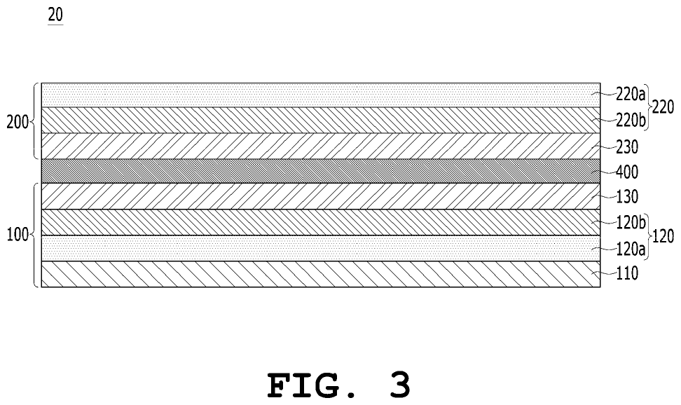

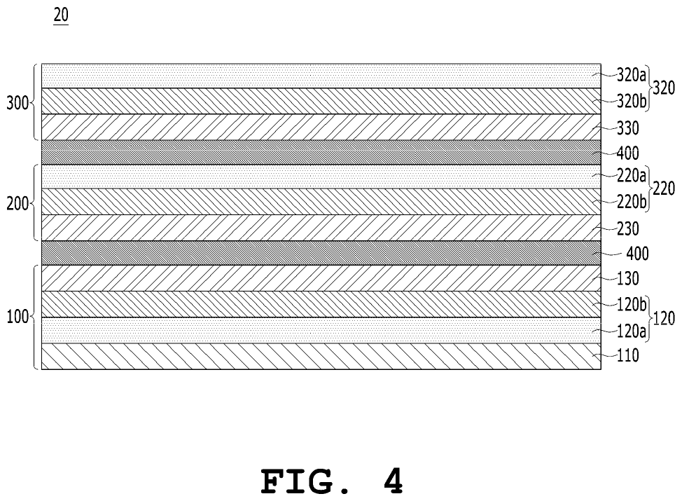

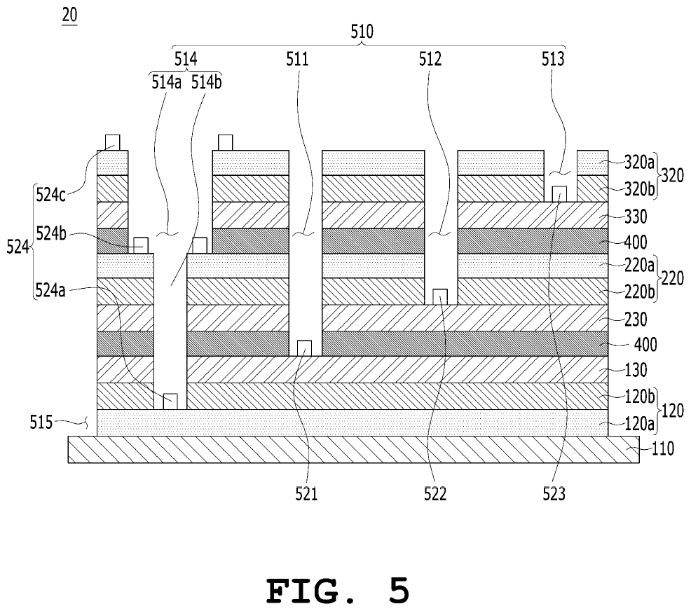

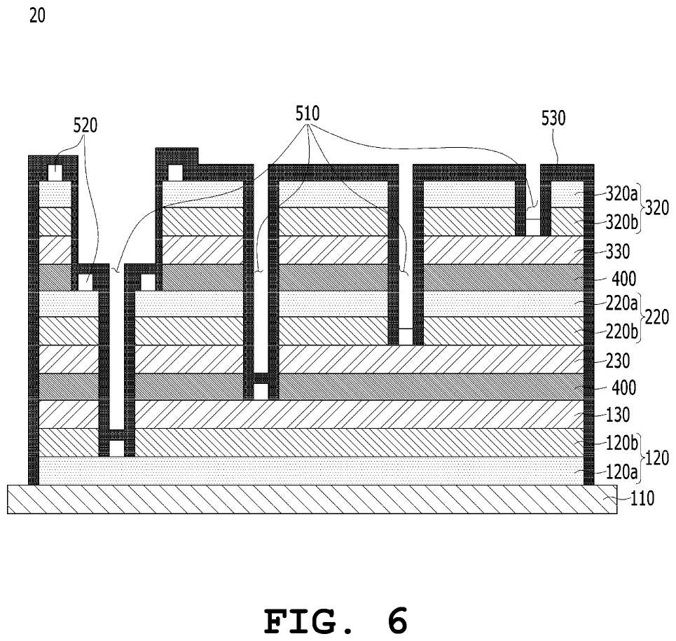

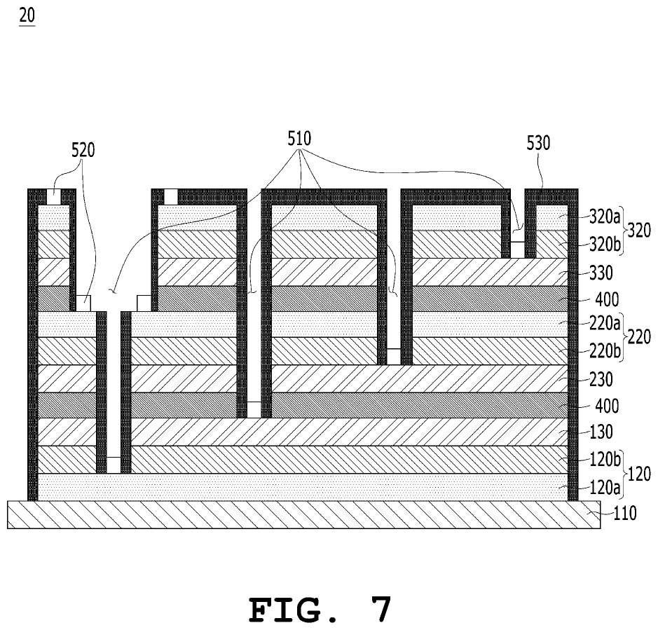

FIG. 2 is a view showing an LED stack 10 including one micro-LED 12. FIG. 3 is a view showing an LED stack 20 including two micro-LEDs 12. FIG. 4 is a view showing the LED stack 20 including three micro-LEDs 12. FIG. 5 is a view showing a state in which a pad electrode 520 is provided in a penetration region 510 formed by etching a part of the LED stack 20. FIG. 6 is a view showing a state in which a protective film 530 is provided on the surfaces of the LED stack 20 and the pad electrode 520. FIG. 7 is a view showing a state in which the protective film 530 provided on the surface of the pad electrode 520 is selectively removed.

Referring to FIGS. 2 to 7, the vertically stacked electronic device 1 according to the embodiment of the present disclosure may include a plurality of micro-LEDs 12. The method for manufacturing the vertically stacked electronic device 1 according to the embodiment of the present disclosure may include: providing an LED stack 20 including the plurality of micro-LEDs 12; providing a pad electrode 520 in a penetration region 510 formed by etching the LED stack 20; providing a protective film 530 on the surfaces of the LED stack 20 and the pad electrode 520; selectively removing the protective film 530 provided on the surface of the pad electrode 520; and providing a bonding electrode 540 in the penetration region 510. In addition, the step of selectively removing the protective film 530 may involve selectively irradiating the protective film 530, where the pad electrode 520 is located, with a laser.

First, the step of providing an LED stack 20 including the plurality of micro-LEDs may be performed.

Referring to FIG. 2, an individual LED stack 10 may include one micro-LED 12. The individual LED stack 10 may include: a substrate 11; the micro-LED 12 located on the substrate 11; and a transparent electrode 13 located on the micro-LED 12.

Referring to FIG. 3, the LED stack 20 may include: a first stack 100; a second stack 200 located on the first stack 100; and a bonding layer 400 for bonding the first stack 100 and the second stack 200.

In this case, the first stack 100 may include a first substrate 110, a first micro-LED 120 on the first substrate 110, and a first transparent electrode 130 on the first micro-LED 120. The second stack 200 may include a second substrate 210, a second micro-LED 220 on the second substrate 210, and a second transparent electrode 230 on the second micro-LED 220.

The second stack 200 may be reversed on the first stack 100, and the first stack 100 and the second stack 200 may be bonded using the bonding layer 400. At this time, the LED stack 20 may include a structure in which the first stack 100, the bonding layer 400, and the inverted second stack 200 are stacked, and the second substrate 210 may be separated from the second stack 200.

Referring to FIG. 4, the LED stack 20 may include: the first stack 100; the second stack 200 located on the first stack 100; a third stack 300 located on the second stack 200; and the bonding layer 400 for bonding the first stack 100 and the second stack 200 and for bonding the second stack 200 and the third stack 300.

In this case, the first stack 100 and the second stack 200 are as described above, and the third stack 300 may include a third substrate 310, a third micro-LED 320 on the third substrate 310, and a third transparent electrode 330 on the third micro-LED 320.

The third stack 300 may be reversed on the second stack 200, and the second stack 200 and the third stack 300 may be bonded using the bonding layer 400. At this time, the LED stack 20 may include a structure in which the first stack 100, the bonding layer 400, the inverted second stack 200, the bonding layer 400, and the inverted third stack 300 are stacked, and the third substrate 310 may be separated from the third stack 300.

As a result, the LED stack 20 including the plurality of micro-LEDs 12, 120, 220, 320 may be provided.

Subsequently, the step of providing the pad electrode 520 in the penetration region 510 formed by etching the LED stack 20 may be performed.

Referring to FIG. 5, the LED stack 20 may include the penetration region 510 with at least a portion thereof is etched. To be specific, the penetration region 510 may include a common penetration region 514, a first penetration region 511, a second penetration region 512, and a third penetration region 513. The LED stack 20 may further include an outer region 515. The outer region 515 refers to an area formed by etching the edge of the LED stack 20, and may extend from the upper surface of the LED stack 20 to the upper surface of the first substrate 110.

The common penetration region 514 may be an area in the LED stack 20 where the common electrode 600 is formed, the first penetration region 511 may be an area where the first electrode 610 is formed, the second penetration region 512 may be an area where the second electrode 620 is formed, and the third penetration region 513 may be an area where the third electrode 630 is formed.

In this case, the common penetration region 514 may include: a first common penetration region 514a formed at the upper portion thereof; and a second common penetration region 514b that is narrower than the first common penetration region 514a.

The common penetration region 514 may penetrate the third micro-LED 320 and the second micro-LED 220 from the upper surface of the vertically stacked electronic device 1 or the LED stack 20, and extend to the first micro-LED 120. At this time, the first common penetration region 514a may extend from the upper surface of the vertically stacked electronic device 1 or the LED stack 20 to the upper surface of the second micro-LED 220, and the second common penetration region 514b may extend from the upper surface of the second micro-LED 220 to the first micro-LED 120. In this case, the second common penetration region 514b may be formed by penetrating a portion of the first micro-LED 120.

The first penetration region 511 may penetrate the third micro-LED 320 and the second micro-LED 220 from the upper surface of the vertically stacked electronic device 1 or the LED stack 20, and extend to the first micro-LED 120. At this time, the first penetration region 511 may be formed by penetrating at least a portion of the first micro-LED 120.

The second penetration region 512 may extend from the upper surface of the vertically stacked electronic device 1 or the LED stack 20 through the third micro-LED 320 to the second micro-LED 220. At this time, the second penetration region 512 may be formed by penetrating at least a portion of the second micro-LED 220.

The third penetration region 513 may extend from the upper surface of the vertically stacked electronic device 1 or the LED stack 20 to the third micro-LED 320. At this time, the third penetration region 513 may be formed by penetrating at least a portion of the third micro-LED 320.

Continuing to refer to FIG. 5, the pad electrode 520 may be provided in the penetration region 510.

The pad electrode 520 may include a common pad electrode 524, a first pad electrode 521, a second pad electrode 522, and a third pad electrode 523. The common pad electrode 524 may include a first common pad electrode 524a, a second common pad electrode 524b, and a third common pad electrode 524c.

The first common pad electrode 524a may be formed on the first micro LED 120. To be specific, the first common pad electrode 524a may be formed on the n-type semiconductor 120a of the first micro LED 120 (n-type). The second common pad electrode 524b may be formed on the second micro LED 220. To be specific, the second common pad electrode 524b may be formed on the n-type semiconductor 220a of the second micro LED 220 (n-type). The third common pad electrode 524c may be formed on the third micro-LED 320. To be specific, the third common pad electrode 524c may be formed on the n-type semiconductor 320a of the third micro LED 320 (n-type).

The first pad electrode 521 may be formed on the first micro LED 120 or on the first transparent electrode 130. The second pad electrode 522 may be formed on the second micro LED 220 or on the second transparent electrode 230. The third pad electrode 523 may be formed on the third micro LED 320 or on the third transparent electrode 330. That is, the first pad electrode 521 to the third pad electrode 523 may be formed to be electrically connected to the p-type semiconductors 120b, 220b, and 320b of the first micro LED 120 to the third micro LED 320, respectively (n-type).

The first common pad electrode 524a, the second common pad electrode 524b, the third common pad electrode 524c, the first pad electrode 521, the second pad electrode 522, and the third pad electrode 523 may be provided at least one each.

Subsequently, the step of providing the protective film 530 on the surfaces of the LED stack 20 and the pad electrode 520 may be performed.

Referring to FIG. 6, the protective film 530 may be provided on the surfaces of the LED stack 20 and the pad electrode 520. The protective film 530 may be made of an insulating material and is not limited to the type thereof. To be specific, the protective film 530 may be provided on the top surface of the LED stack 20, on the top and side surfaces of the pad electrode 520, and on the side surfaces of the LED stack 20.

The protective film 530 may be used to block electrical conduction except for specific areas of the micro LEDs 12, 120, 220, and 320 that require electrical connection with the common electrode 600, the first electrode 610, the second electrode 620, and the third electrode 630.

Subsequently, the step of selectively removing the protective film 530 provided on the surface of the pad electrode 520 may be performed.

Referring to FIG. 7, the protective film 530 provided on the surface of the pad electrode 520 may be removed. As a result, the pad electrode 520 may contact the bonding electrode 540, which will be described later, and the pad electrode 520 may be combined with the bonding electrode 540 to form the common electrode 600, the first electrode 610, the second electrode 620, and the third electrode 630.

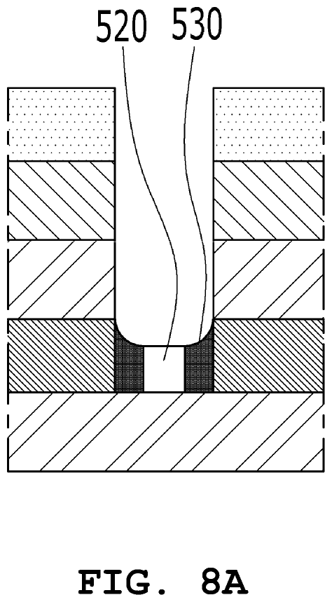

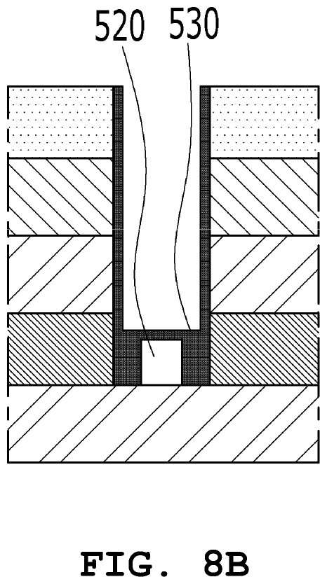

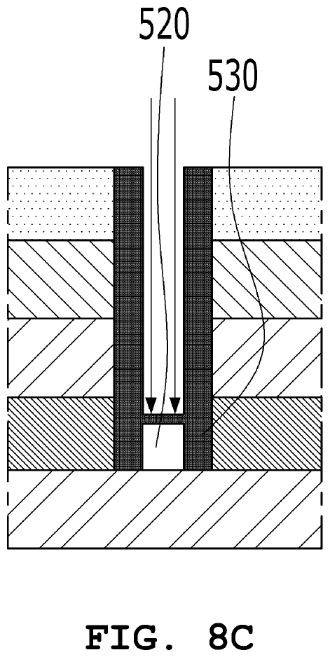

FIG. 8A is a view showing a state in which the protective film 530 on the part other than the surface of the pad electrode 520 is etched. FIG. 8B is a view showing a state in which the protective film 530 on the part other than the surface of the pad electrode 520 is etched. FIG. 8C is a view showing a state in which the protective film 530 on the surface of the pad electrode 520 is selectively etched according to an embodiment of the present disclosure.

The protective film 530 may be selectively removed by a laser light source.

Referring to FIG. 8A, the protective film 530 formed on the upper surface of the pad electrode 520 has been removed, but the protective film 530 formed on the sides of the LED stack 20 has also been removed. This is a situation that may occur when the protective film 530 is subjected to general wet etching.

Referring to FIG. 8B, the protective film 530 formed on the upper surface of the pad electrode 520 is being removed, but the protective film 530 formed on the sides of the LED stack 20 has also been removed. This is a situation that may occur when the protective film 530 is subjected to general dry etching.

Referring to FIG. 8C, only the protective film 530 formed on the upper surface of the pad electrode 520 is selectively removed. When etching the protective film 530 with a laser light source, only the protective film 530 may be selectively etched due to straightness, so etching precision may be improved.

In particular, because the protective film 530 is made of the same material, the protective film 530 on a portion other than the surface of the pad electrode 520 may be etched by reacting with the etching gas and/or the etching solution. As a result, a short circuit may occur between the micro-LEDs 12.

The method for manufacturing the vertically stacked electronic device 1 according to the embodiment of the present disclosure may improve etching precision by selectively etching the protective film 530 on the pad electrode 520 using a laser, and prevent short circuit of the vertically stacked electronic device 1.

Subsequently, the step of providing the bonding electrode 540 in the penetration region 510 may be performed.

The bonding electrode 540 may contact the pad electrode 520 to form the common electrode 600, the first electrode 610, the second electrode 620, and the third electrode 630. That is, the common electrode 600 may include a common bonding electrode (not shown) and the common pad electrode 524, the first electrode 610 may include a first bonding electrode (not shown) and the first pad electrode 521, the second electrode 620 may include a second bonding electrode (not shown) and the second pad electrode 522, and the third electrode 630 may include a third bonding electrode (not shown) and the third pad electrode. The bonding electrode may be formed to protrude further from the upper surface of the vertically stacked electronic device or LED stack 20. As a result, the vertically stacked electronic device 1 can be more easily electrically connected to an external power source.

The vertically stacked electronic device 1 according to the embodiment of the present disclosure makes it possible to manufacture a display with high-density pixels by stacking the plurality of micro LEDs 12, 120, 220, and 320 in the vertical direction. Furthermore, the method for manufacturing the vertically stacked electronic device 1 according to the embodiment of the present disclosure makes it possible to prevent short circuit defects in the vertically stacked electronic device 1 by precisely etching the protective film 530 using a laser light source.

As described above, although it has been described with reference to preferred embodiments of the present disclosure, those skilled in the art may variously modify or change the present disclosure within the scope without departing from the spirit and scope of the present disclosure described in the claims below.

What is claimed is:

1. A vertically stacked electronic device formed by stacking a plurality of micro-LEDs in a vertical direction, the electronic device comprising:
a substrate;
a first micro-LED located on the substrate;
a second micro-LED located on the first micro-LED;
a third micro-LED located on the second micro-LED;
a common electrode provided through the third micro-LED, the second micro-LED, and the first micro-LED;
a first electrode that penetrates the electronic device and is electrically connected to the first micro-LED;
a second electrode that penetrates the electronic device and is electrically connected to the second micro-LED; and
a third electrode that penetrates the electronic device and is electrically connected to the third micro-LED.

2. A method for manufacturing a vertically stacked electronic device including a plurality of micro-LEDs, the method comprising:
providing an LED stack including the plurality of micro-LEDs;
providing a pad electrode in a penetration region formed by etching the LED stack;
providing a protective film on surfaces of the LED stack and the pad electrode;
selectively removing the protective film provided on the surface of the pad electrode; and
providing a bonding electrode in the penetration region.

3. The method of claim 2, wherein in the selectively removing the protective film, the protective film, where the pad electrode is located, is selectively irradiated with a laser.
